(19) United States
(12) Patent Application Publication
(10) Pub. No.: US 2008/0151591 A1
(43) Pub. Date: Jun. 26, 2008

(54) Memory system with a configurable number of read data bits

(75) Inventors: Kevin J. Doran, North Plains, OR (US); Joseph H. Salmon, Placerville, CA (US); Michael W. Williams, Folsom, CA (US)

Correspondence Address: INTEL/BLAKELY, 1279 OAKMEAD PARKWAY, SUNNYVALE, CA, 94085-4040, US

(73) Assignee: Intel Corporation

(21) Appl. No.: 11/644,607

(22) Filed: Dec. 21, 2006

(51) Int. Cl. G11C 5/06; H05K 5/00

(52) U.S. Cl. 365/63; 361/736

(57) ABSTRACT

In some embodiments, a chip includes transmitter circuitry, receiver circuitry, and control circuitry to detect whether a memory module is coupled to the receiver circuitry. The control circuitry selectively provides memory chip configuration signals to the transmitter circuitry to be provided to memory chips to control how many interface lanes in the memory chips are to be used to carry read data in response to a read request and whether some of the interface lanes are used for carrying read data signals or command signals. Other embodiments are described.

### BACKGROUND

1. Technical Field

The present inventions relate to memory systems and, in particular, to memory systems in which the memory chips provide a configurable number of read data bits.

2. Background Art

Various arrangements for memory chips in a memory system have been proposed. For example, in a traditional synchronous dynamic random access memory (DRAM) system, memory chips communicate data through bidirectional data buses and receive commands and addresses through command and addresses buses. The memory chips have stubs that connect to the buses. Other memory systems use unidirectional signaling. Some memory systems use a multi-drop signaling arrangement in which signals are transmitted to more than one receiver. Other memory systems use point-to-point signaling in which signals are transmitted to only one receiver.

In some memory systems, a memory chip receives signals and repeats them to a next memory chip in a series of two or more memory chips. In some of these systems, the last memory chip in the series can send a signal directly back to a memory controller. This is referred to as a ring. In some such systems, a memory chip provides some read data signals while also providing commands to another memory chip which provides additional read data signals. Unidirectional lanes have been used to carry packetized command, address, and write data signals, along with clocks signals, between memory controllers and memory chips, and between memory chips. The signals carrying write data may be separate from the signals carrying command and address signals. Status bits may be carried with the read data.

In some memory systems, some memory chips are populated on the motherboard that supports the chip containing the memory controller, while other memory chips are on a memory module that is on a different printed circuit board. The memory chips on the mother board are said to be “down,” while the memory chips on the memory module are said to be “up.” In some cases, these memory chips and the associated memory controller may have a limited number of balls (or pins) for interfacing outside them. This can create difficulty in having them each transmit and receive a relatively large number of data bits while some of the memory chips also provide commands to others of the memory chips.

SO-DIMMs are small outline dual in-line memory modules that are smaller than some other memory modules. They are often used in mobile computers. SFF (small form factor) is a generic term used for motherboards that are typically smaller than prevalent mobile computer sizes.

Ranks involve memory chips that are accessed together.

Memory modules include a substrate on which a number of memory chips are placed. The memory chips may be placed on only one side of the substrate or on both sides of the substrate. In some systems, a buffer is also placed on the substrate. For at least some signals, the buffer interfaces between the memory controller and the memory chips on the module. In such a buffered system, the memory controller can use different signaling (for example, frequency and voltage values, and point-to-point versus a multi-drop arrangement) with the buffer than the buffer uses with the memory chips.

Some memory controllers are included in processor chips that include processor cores. The processor chips are coupled to an input/output controller. Other memory controllers are included in memory controller hubs that are coupled to an input/output controller. In some implementations, the input/output controllers may be coupled to wireless transmitting and receiving circuitry.

### BRIEF DESCRIPTION OF THE DRAWINGS

The inventions will be understood more fully from the detailed description given below and from the accompanying drawings of embodiments of the inventions which, however, should not be taken to limit the inventions to the specific embodiments described, but are for explanation and understanding only.

FIG. 1 is a block diagram representation of memory system including a memory controller, a first group of memory chips on a circuit board, and a continuity card according to some embodiments of the inventions.

FIG. 2 is a block diagram representation of memory system including a memory controller, a first group of memory chips on a motherboard, and a memory module according to some embodiments of the inventions.

FIG. 3 is a block diagram representation of details of a memory chip including some external conductors according to some embodiments of the inventions.

FIG. 4 is a block diagram representation of two memory chips including some external conductors according to some embodiments of the inventions.

FIG. 5 is a block diagram representation of memory system including a first group of memory chips on a motherboard, and a memory module according to some embodiments of the inventions.

FIG. 6 is a block diagram representation of memory system including a memory controller, a first group of memory chips on a motherboard, and a memory module according to some embodiments of the inventions.

FIG. 7 is a block diagram representation of a system including a chip with processor cores and a memory controller, an input/output controller chip, and wireless transmitter and receiver circuitry according to some embodiments of the inventions.

FIG. 8 is a block diagram representation of a system including a chip with processor cores, a chip with a memory controller, an input/output controller chip, and wireless transmitter and receiver circuitry according to some embodiments of the inventions.

### DETAILED DESCRIPTION

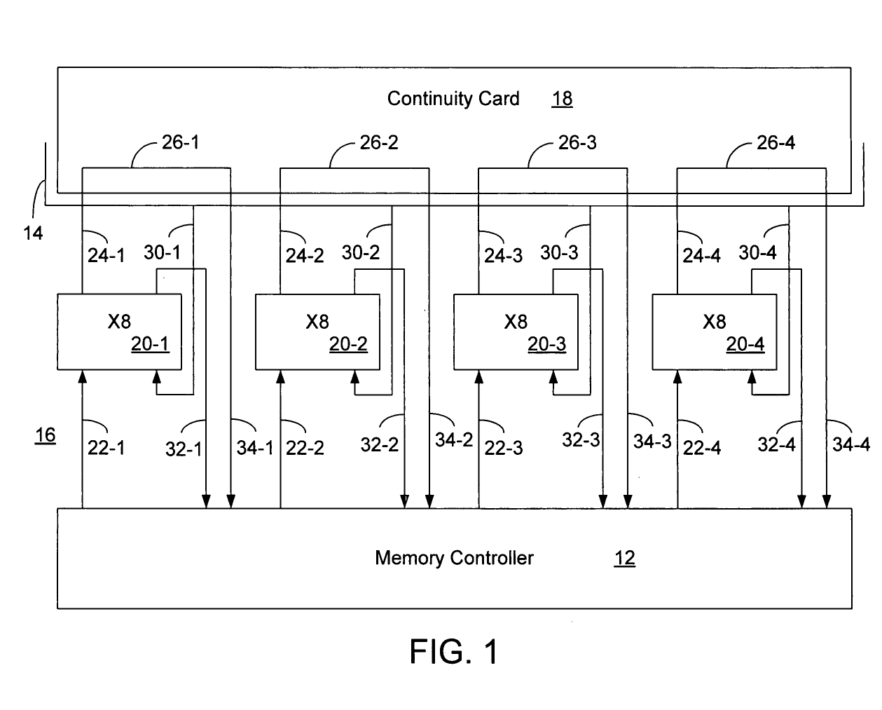

Referring to FIG. 1, a system includes a memory controller 12 coupled to memory chips 20-1, 20-2, 20-3, and 20-4, which are supported by a circuit board 16. A motherboard supports the chips that includes memory controller 12. A continuity card 18 (also called a continuity module) is inserted in a slot 14. Memory chips on the circuit board are referred to as being “down.”

In the example of FIG. 1, command, address, and write data signals are carried from memory controller 12 on conductors 22-1, 22-2, 22-3, and 22-4 to chips 20-1, 20-2, 20-3, and 20-4. If the commands are read commands, chips 20-1, 20-2, 20-3, and 20-4 respond by providing four bits of read data to conductors 24-1, 24-2, 24-3, and 24-4, and four bits of read data to conductors 32-1, 32-3, 32-3, and 32-4. Conductors 32-1, 32-2, 32-3, and 32-4 couple chips 20-1, 20-2, 20-3, and 20-4 to memory controller 12. Conductors 32-1, 32-2, 32-3, and 32-4 pass primarily through circuit board 16, but may also include other structures such as pads and vias.

By contrast, conductors 24-1, 24-2, 24-3, and 24-4 do not directly couple chips 20-1, 20-2, 20-3, and 20-4 to memory controller 12, but rather conductors 24-1, 24-2, 24-3, and 24-4 couple chips 20-1, 20-2, 20-3, and 20-4 to slot 14. When continuity card 18 is inserted in slot 14, conductors 24-1, 24-2, 24-3, and 24-4 are coupled to conductors 26-1, 26-2, 26-3, and 26-4 of continuity card 18. In turn, conductors 26-1, 26-2, 26-3, and 26-4 are coupled to memory controller 12 through conductors 34-1, 34-2, 34-3, and 34-4.

As an example, conductors 24-1-24-4, 26-1-26-4, and 34-1-34-4 each include four, lanes for read data and one lane for a clock signal. Accordingly, when chip 20-1 is in a X8 (eight bit) mode, four read data bits and a clock signal are provided through conductors 32-1 and another four read data bits and a clock signal are provided through conductors 24-1, 26-1, 34-1. Likewise, when chips 20-2, 20-3, and 20-4 are in a X8 (eight bit) mode, four read data bits and a clock signal are provided through each of conductors 32-2, 32-3, and 32-4, and another four read data bits and a clock signal are provided through each of conductors 24-2, 26-2, and 34-2; 24-3, 26-3 and 34-3; 24-4, 26-4, and 34-4. In some embodiments or modes within embodiments, chip 20-1 provides eight bits in response to a single read command, and in other embodiments or modes within embodiments, chip 20-1 provides multiple groups of eight bits in series (bursts) in response to a single read command. Likewise, with chips 20-2, 20-3, and 20-4.

Conductors 24-1, 24-2, 24-3, and 24-4, conductors 26-1, 26-2, 26-3, and 26-4, and conductors 34-1, 34-2, 34-3, and 34-4 may include pads and vias. A lane may include a single conductor with single ended signaling and two conductors with differential signaling. The command, address, and write data signals may be carried in frames or packets. However, in other embodiments, the commands, addresses, and write data signals are not conducted on the same conductors.

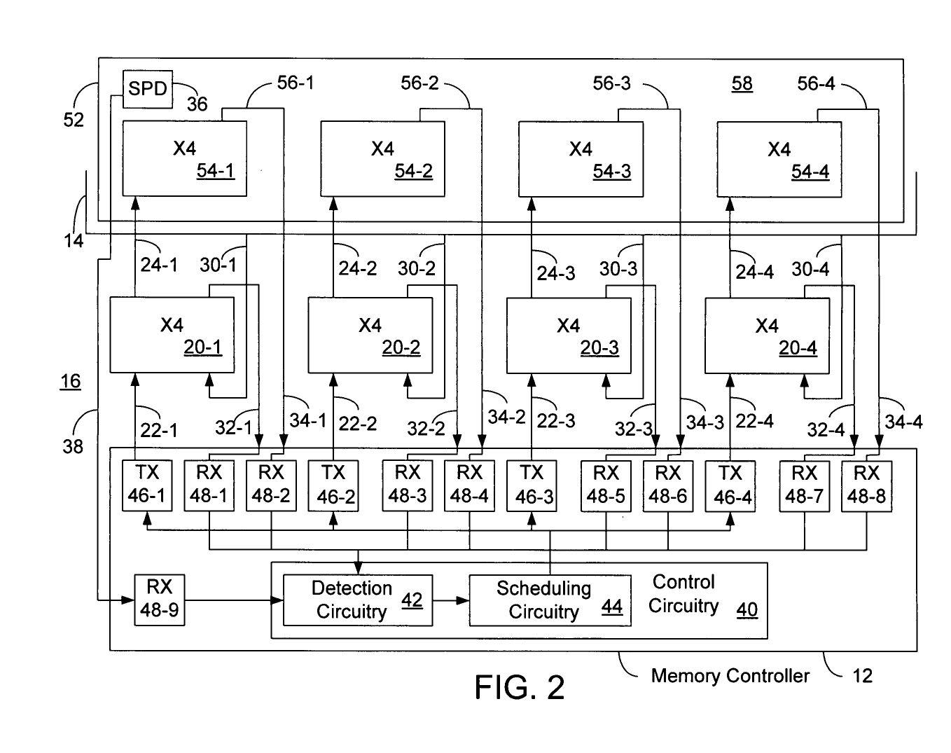

Referring to FIG. 2, a memory module 52 is inserted slot 14. Memory module 52 includes memory chips 54-1, 54-2, 54-3, and 54-4. In the following discussion, it is assumed that memory chips 54-1-54-4 are fabricated to be identical to memory chips 20-1-20-4 (although they are implemented differently in FIG. 2). In other embodiments, memory chips 54-1-54-4 may be fabricated to be different than memory chips 20-1-20-4. Memory module 54 includes a substrate 58. In some embodiments, memory chips are on only one side of substrate 58 and in other embodiments, memory chips are on both sides of substrate 58. Conductors 22-1-22-4, 32-1-32-4, and 34-1-34-4 are part of one channel, and there may be one or more additional channels coupling memory controller 12 to additional memory chips (not shown).

Memory chips on motherboard 16 are referred to as “down” chips or being “down.” Memory chips on memory module 52 are referred to as “up” chips or being “up.” Memory controller 12 includes control circuitry 40, transmitter circuitry 46, and receiver circuitry 48. Transmitter circuitry 46 includes transmitters 46-1, 46-2, 46-3, and 46-4 which transmit signals on conductors 22-1, 22-2, 22-3, and 24-4. Receivers 48 includes receivers 48-1, 48-2, 48-3, 48-4, 48-5, 48-6, 48-7, 48-8, and 48-9 which receive signals from conductors 32-1, 34-1, 32-2, 34-2, 32-3, 34-3, 32-4, 34-4, and 38. Control circuitry 40 includes detection circuitry 42 and scheduling circuitry 44. Detection circuitry 42 detects whether a memory module is inserted in slot 14. In different embodiments, there are different techniques for detection circuitry 42 to detect whether a memory module is inserted in slot 14.

In some embodiments, a memory module 52 includes a serial presence detect memory (SPD) 36 that is coupled to receiver circuitry 48-9 through conductors 38 when memory module 52 is inserted in slot 14. When the system is first powered on, and/or from time to time after it is first powered on, memory controller 12 attempts to read the contents of the SPD. In the case of FIG. 1, there is no SPD, so memory controller 12 is unable to read signals indicating memory controller 12 is coupled to a memory module. Accordingly, detection circuitry 42 concludes that a memory module 12 is not coupled to memory controller 12. Alternatively, continuity card 18 could include an SPD that indicates it is on a continuity card.

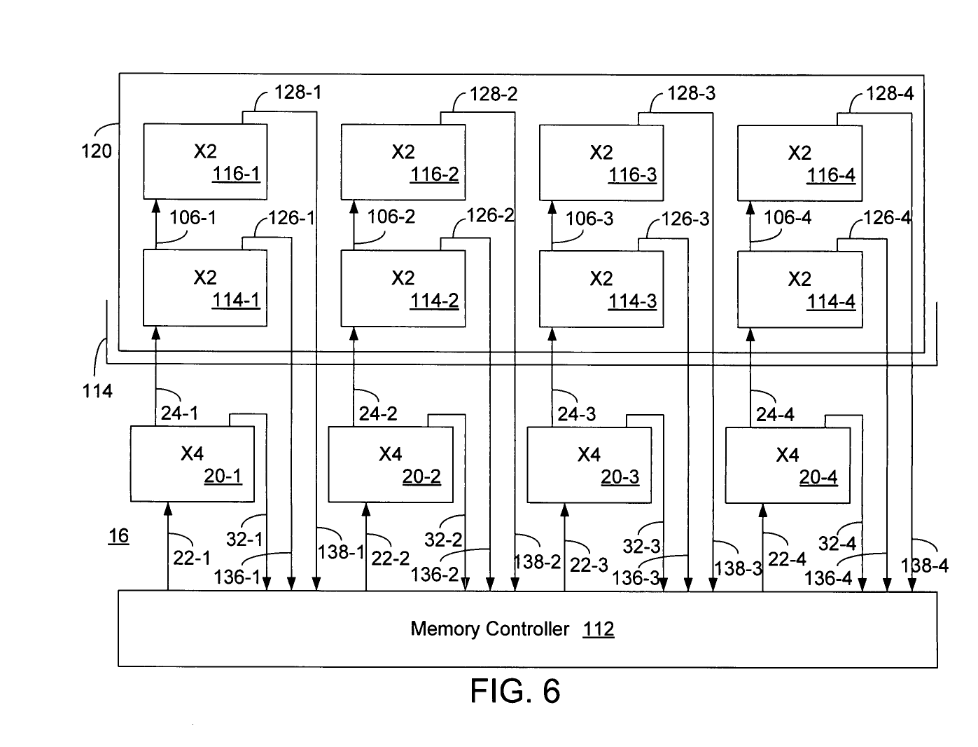

When an appropriate signal from SPD 36 is received by receiver circuitry 48-9, detection circuitry 42 interprets the signaling as indicating that a memory module is coupled to memory module 12 (inserted in slot 14). In some embodiments, SPD signals may also indicate a variety of things about the module and the memory chips on the module. For example, the SPD signals may indicate how many memory chips are on the memory module (for example, compare FIGS. 2 and 6).

When detection circuitry 42 detects that a memory module is inserted in slot 14, it provides a signal indicating this to scheduling circuitry 44. Scheduling circuitry 44 provides memory chip configuration signals (commands) to chips 20-1-20-4 to place them in particular modes. At least some of the commands are passed by chips 20-1-20-4 to chips 54-1-54-4 to place them in particular modes. For example, the commands may place chips 20-1-20-4 and 54-1-54-4 in X4 modes described below. In some embodiments, chips 20-1-20-4 and 54-1-54-4 are in a X8 mode by default and have to be changed to a X4 mode. In other embodiments, chips 20-1-20-4 and 54-1-54-4 are in a X4 mode by default and have to be changed to a X8 mode. In still other embodiments, chips 20-1-20-4 and 54-1-54-4 are not in any mode by default and have to be set to a mode. In some embodiments, there may be other modes such as X16 or X2 modes. Control circuitry 40 is said to “selectively” provide the memory chip configuration signals to the transmitter circuitry because, as explained, under some situations, control circuitry 40 does provide the memory chip configuration signals and under some situations, control circuitry 40 does not provide the memory chip configuration signals.

In some embodiments, detection circuitry 42 detects whether a memory module is inserted in slot 14 through a technique other than or in addition to reading an SPD. For example, in some embodiments, detection circuitry 42 receives signals from one or more of receiver circuitry 48-2, 48-4, 48-6, and 48-8 to determine whether they are coupled to a memory module. In some embodiments, the available addresses could be different depending on whether a module is inserted. In some embodiments, detection circuitry 42 could observe timing differences between signals on conductors 32-1-32-4 and 34-1-34-4, although in other embodiments, there are not meaningful timing differences.

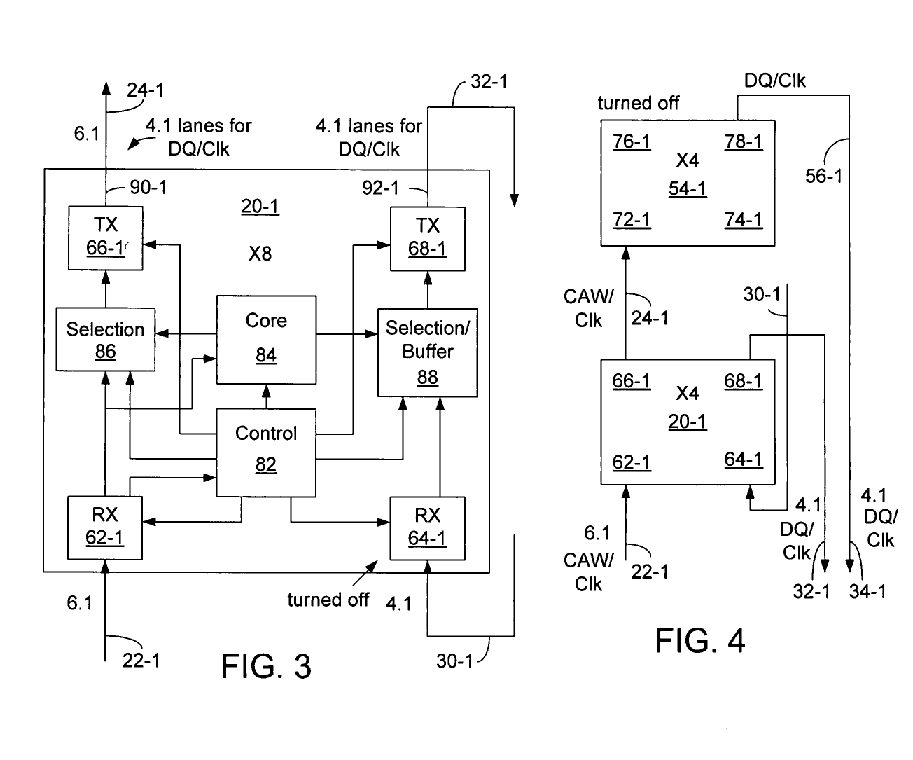

FIG. 3 illustrates details of memory chip 20-1 according to some embodiments. In FIG. 3, conductors 22-1 include seven lanes (6.1): six lanes for carrying command, address, and write data signals which are in packetized form (CAW), and one lane for carrying a clock signal (Clk) for them. The CAW/Clk signals are received by receivers 62-1, which provides them to control circuitry 82, memory core 84, selection circuitry 86. A command signal may instruct control circuitry 82 whether chip 20-1 should be in X4 or X8 mode. In the example of FIG. 3, memory chip 20-1 is in a X8 mode as in FIG. 1. As noted, in some embodiments, the default is X8 mode so that no command is necessary to place it in a X8 mode. In other embodiments, it must be placed in a X8 mode.

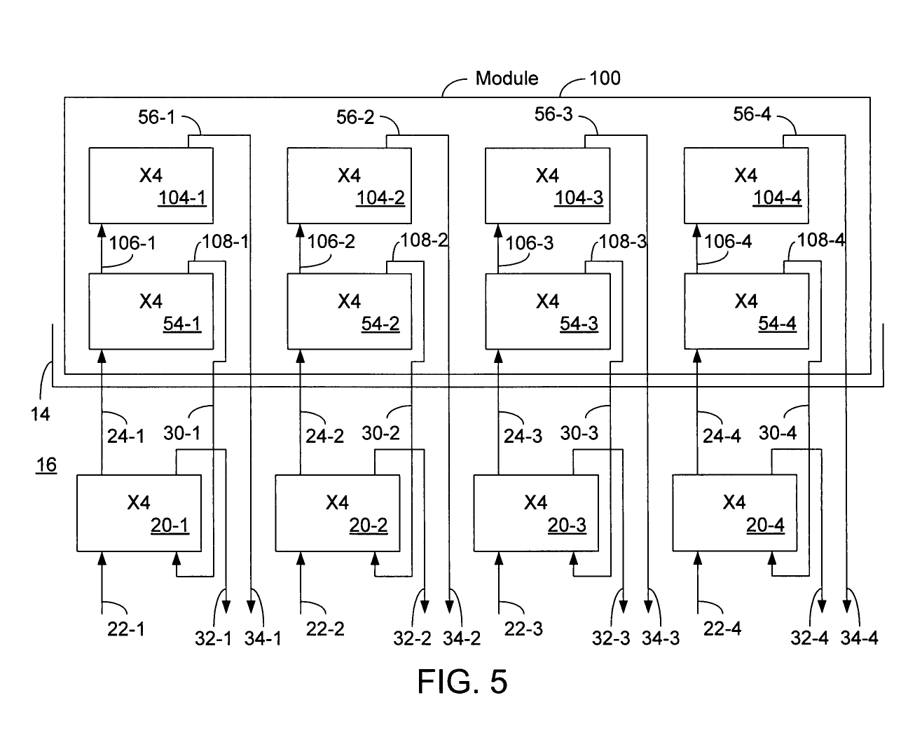

In a X8 mode, transmitters 66-1 transmit 4 bits of read data and a clock signal to internal conductors 90-1 which are coupled to external conductors 24-1. In a X4 mode (as shown in FIG. 4), transmitters 66-1 transmit CAW/Clk signals. In either mode, transmitters 68-1 transmit 4 bits of read data and a clock signal to internal conductors 92-1 and external conductors 32-1 in response to a read command. Selection circuitry 86 selects between providing read data from core 84 (and a clock signal) and CAW/Clk signals to transmitters 66-1. Selection circuitry/buffer 88 selects between providing read data from core 84 (and a clock signal) or read data (and a clock signal) from receivers 64-1. In the example of FIG. 3, receivers 64-1 are turned off, but they are turned on in the example of FIG. 5.

In FIG. 4, chips 20-1 and 54-1 are in X4 modes. Chip 54-1 includes receivers 72-1 and 74-1 like receivers 62-1 and 64-1, and transmitters 76-1 and 78-1 like transmitters 66-1 and 68-1. CAW/Clk signals are provided on seven lanes from transmitters 66-1 to receivers 72-1. Four bits of read data and a clock signal are provided on five lanes from transmitters 68-1 to conductors 32-1. Transmitters 76-1 are turned off, unless there is another chip coupled to chip 54-1 as in FIGS. 5 and 6. Receivers 64-1 and 74-1 are turned off. Transmitters 78-1 provide 4 bits of read data and a clock signal on five lanes of conductors 56-1 which are coupled to conductors 34-1.

FIG. 5 illustrates a memory module 100 which includes eight memory chips: chips 54-1-54-1 plus memory chips 104-1, 104-2, 104-3, and 104-4. Chips 54-1, 54-2, 54-3, and 54-4 provide chips 104-1, 104-2, 104-3, and 104-4 CAW/Clk signals through conductors 106-1, 106-2, 106-3, and 106-4. In response to a read command, chips 20-1-20-4 provide read data signals to conductors 32-1-32-4, and chips 104-1, 104-2, 104-3, and 104-4 provide four bits of read data through conductors 56-1, 56-2, 56-3, and 56-4 to conductors 34-1, 34-2, 34-3, and 34-4 and the memory controller. Further, in response to a read command, chip 54-1 provides four bits of read data through conductors 108-1 to receivers 64-1 of chip 20-1 (see FIG. 3). In the case of FIG. 5, chip 20-1 is in a mode in which receivers 64-1 pass the read data to selection/buffer circuitry 88 which holds the read data until it to transmitted by transmitters 68-1 to conductors 32-1 and the memory controller. In the modes of FIG. 5, selection/buffer circuitry 88 in FIG. 3 takes turns between providing read data from memory core 84 and read data in the buffer of selection buffer circuitry 88. The memory controller is configured to expect this staggered data. Chips 54-2, 54-3, and 54-4 also provide four bits of read data to conductors 108-2, 108-3, and 108-4 to receivers like receivers 64-1 in chips 20-2, 20-3, and 20-4. In some embodiments, memory controller 12 can operate in a system like the system of FIG. 5 and in other embodiments, it does not.

FIG. 6 is like FIG. 5 except that module 120 includes eight memory chips 114-1, 114-2, 114-3, 114-4, 116-1, 116-2, 116-3, and 116-4, which are in a X2 mode rather than a X4 mode and each of the chips provide two read data bits (and a clock signal) to memory controller 112. Chips 114-1-114-4, and 116-1-116-4 may be identical to or different than chips 20-1-20-4 (although implemented differently), Chips 114-1, 114-2, 114-3, and 114-4 each provide two read data bits (and a clock signal) through conductors 126-1 and 136-1, 126-2 and 136-2, 126-3 and 136-3, and 126-4 and 136-4. Chips 116-1, 116-2, 116-3, and 116-4 each provide two read data bits (and a clock signal) through conductors 128-1 and 138-1, 128-2 and 138-2, 128-3 and 138-3, and 128-4 and 138-4. In some embodiments, there is a shared clock signal. Chips 20-1-20-4 do not receive read data signals from chips on memory module 120 (as in FIG. 5). In some embodiments, memory controller 12 can perform the functions of memory controller 112 and in other embodiments, it cannot.

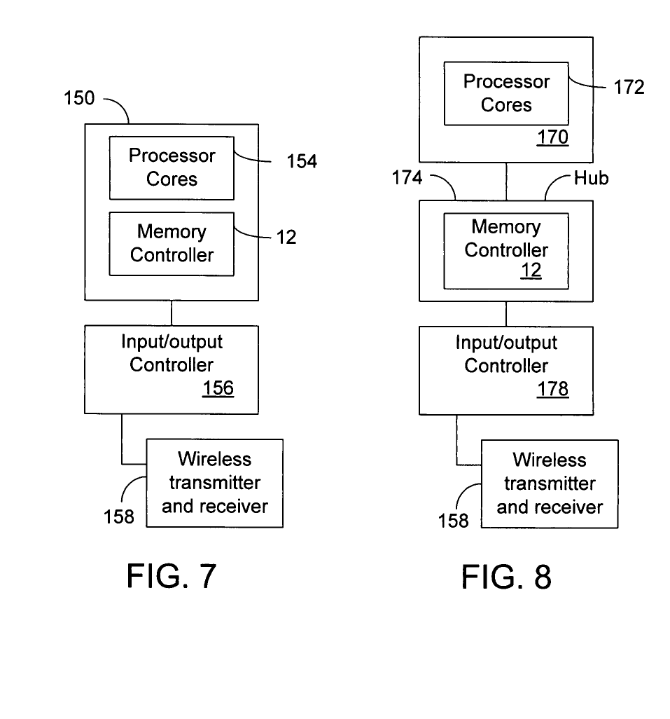

FIGS. 7 and 8 illustrate that memory controller 12 can be in different chips. For example, in FIG. 7, memory controller 12 is part of a processor chip 150 that includes processor cores 154. Processor chip 150 is coupled to an input/output controller 156 which is coupled to wireless transmitter and receiver circuitry 158. In FIG. 8, memory controller 12 is part of a hub chip 174 which is coupled between a processor chip 170 that includes processor cores 172 and an input/output controller 178. Input/output controller 178 is coupled to wireless transmitter and receiver circuitry 158.

### Other Information and Embodiments

In some embodiments, a rank is formed of chips that provide 32 read data bits. For example, in these embodiments, in FIG. 1, chips 20-1-20-4 would form a rank, and in FIG. 2, chips 20-1-20-4 and 54-1-54-4 would form a rank. The system may include additional ranks not illustrated in the figures. In some cases, the rank may provide a number of read data bits that is different than 32 bits (FIG. 5).

In some embodiments, the invention involves dynamically reconfiguring memory chips to provide a different number of read bits, while a rank including the memory chips continues to provide the same number of read data bits.

The invention could be used in a system including a buffer on the motherboard, wherein the buffer interfaces with the down memory chips, and another buffer on the memory module, wherein the other buffer interfaces with the up memory chips.

Status bits may be carried with the read data bits.

SO (small outline) modules and SFF systems may be used, but this is not required. Indeed, the invention may be used in a variety of systems with various types of memory modules. Modules other than DIMMs may be used.

The chip interface balls used and the arrangement of the conductors may be such as to avoid crossing conductors between chips.

The conductors mentioned herein do not have to be of continuous material. For example, they may include vias or other connection structures.

The inventions are not restricted to any particular signaling techniques or protocols. For example, the signaling may be single ended or differential. The signaling may include only two voltage levels or more than two voltage levels. The signaling may be single data rate, double data rate, quad data rate, or octal data, etc. The signaling may involve encoded symbols and/or packetized signals. A clock (or strobe) signal may be transmitted separately from the other signals or embedded in the other signals. Various coding techniques may be used. Strobe signals could be used rather than clock signals. Write buffers may be included in the memory chips. The write data signals do not have to be on the same conductor lanes as the address and command signals.

The figures are shown and described with unidirectional point-to-point signaling. However, some embodiments may include bi-directional signaling on some conductors and include some multi-drop rather than point-to-point conductors.

There may be intermediate structure between the memory controller chip, memory chips, and connector and the motherboard. The various chips described or illustrated herein may have additional inputs or outputs which are not illustrated or described. In actual implementations of the systems of the figures, there would be additional circuitry, control lines, and perhaps interconnects which are not illustrated. When the figures show two blocks connected through conductors, there may be intermediate circuitry that is not illustrated. The shape and relative sizes of the blocks is not intended to relate to actual shapes and relative sizes.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments.

When it is said the element “A” is coupled to element “B,” element A may be directly coupled to element B or be indirectly coupled through, for example, element C.

When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.”

If the specification states a component, feature, structure, process, or characteristic “may”, “might”, or “could” be included, that particular component, feature, structure, process, or characteristic is not required to be included. If the specification or claim refers to “a” or “an” element, that does not mean there is only one of the element.

The inventions are not restricted to the particular details described herein. Indeed, many other variations of the foregoing description and drawings may be made within the scope of the present inventions. Accordingly, it is the following claims including any amendments thereto that define the scope of the inventions.

What is claimed is:

1. A chip comprising:
transmitter circuitry and receiver circuitry; and
control circuitry to detect whether a memory module is coupled to the receiver circuitry and in response thereto to selectively provide memory chip configuration signals to the transmitter circuitry to be provided to memory chips to control how many interface lanes in the memory chips are to be used to carry read data in response to a read request and whether some of the interface lanes are used for carrying read data signals or command signals.

2. The chip of claim 1, wherein when the control circuitry detects the coupling of the memory module, the memory chip configuration signals cause a first number of interface lanes to be used to carry the read data, and wherein when the control circuitry does not detect the coupling, the memory chip configuration signals cause a second number of interface lanes to be used to carry the read data.

3. The chip of claim 1, wherein the first number is four and the second number is eight.

4. The chip of claim 1, wherein when the control circuitry causes different memory chips to have a different number of interface lanes to be used to carry the read data.

5. The chip of claim 1, wherein when the control circuitry detects the coupling of the memory module, the memory chip configuration signals cause a first number of interface lanes to be used to carry the read data, and wherein when the control circuitry does not detect the coupling, the control circuitry does not provide the memory chip configuration signals to the transmitter circuitry.

6. The chip of claim 1, wherein the detection is made at initial powering of the chip.

7. The chip of claim 1, wherein the detection is made at initial powering of the chip and in response to a memory module being inserted or removed after initial powering of the chip.

8. The chip of claim 1, wherein the memory chip configuration signals are also to control whether certain transmitter circuitry in a second group of the memory chips is operational.

9. The chip of claim 8, wherein the memory chip configuration signals are also to control whether certain receivers in the second group of the memory chips is operational.

10. The chip of claim 1, wherein the control circuitry has a mode in which it expects a first group of read data signals directly from a first group of memory chips, a second group of read data signals directly from a second group of memory chips, and a third group of read data signals from the third group of memory chips through the second group of first chips.

11. A system comprising:
a first group of memory chips on a circuit board;
an additional chip on the circuit board including:
transmitter circuitry and receiver circuitry; and
control circuitry to detect whether a memory module is coupled to the receiver circuitry and in response thereto to selectively provide memory chip configuration signals to the transmitter circuitry to be provided to memory chips to control how many interface lanes in the memory chips are to be used to carry read data in response to a read request and whether some of the interface lanes are used for carrying read data signals or command signals.

12. The system of claim 11, further comprising the memory module including a second group of memory chips, and wherein the first and second groups of memory chips are configured to be one rank.

13. The system of claim 12, wherein the second group of memory chips includes more memory chips than the first group of memory chips.

14. The system of claim 13, wherein the first and second groups of memory chips are configured to have the same number of interface lanes carry read data.

15. The system of claim 13, wherein the second group of memory chips is configured to have a different number of interface lanes carry read data than the first group of memory chips.

16. The system of claim 11, wherein when the control circuitry detects the coupling of the memory module, the memory chip configuration signals cause a first number of interface lanes to be used to carry the read data, and wherein when the control circuitry does not detect the coupling, the memory chip configuration signals cause a second number of interface lanes to be used to carry the read data.

17. The system of claim 11, wherein when the control circuitry detects the coupling of the memory module, the memory chip configuration signals cause a first number of interface lanes to be used to carry the read data, and wherein when the control circuitry does not detect the coupling, the control circuitry does not provide the memory chip configuration signals to the transmitter circuitry.

18. The system of claim 11, wherein the additional chip includes processing cores, and the additional chip is coupled to wireless transmitting and receiving circuitry.

19. A chip comprising:
a first group of chip interface receivers, a first group of chip interface transmitters and a second group of chip interface transmitters;
a memory core; and
control circuitry to receive a configuration command through the first group of receivers and in response the configuration command to control whether read data from the memory core is to be provided to only the first group of transmitters or to both the first and second groups of transmitters, wherein the control circuitry is to control whether the second group of transmitters is to provide read data from the memory core or to pass on command signals received through the first group of receivers.

20. The chip of claim 19, further comprising a second group of chip interface receivers, and wherein the control circuitry is to control whether the second group of receivers is operational in response to the configuration command.

21. The chip of claim 19, further comprising a buffer to temporarily hold read data from another chip.
